(19) United States
(12) Patent Application Publication
(10) Pub. No.: US 2025/0295012 A1
(43) Pub. Date: Sep. 18, 2025

(54) DISPLAY DEVICE AND DISPLAY SYSTEM INCLUDING THE SAME

(71) Applicant: Samsung Display Co., LTD., Yongin-si (KR)

(72) Inventors: So Yeon YOON, Yongin-si (KR); Ji Wook MOON, Yongin-si (KR); Gwang Geun LEE, Yongin-si (KR)

(73) Assignee: Samsung Display Co., LTD., Yongin-si (KR)

(21) Appl. No.: 18/977,176

(22) Filed: Dec. 11, 2024

(30) Foreign Application Priority Data
Mar. 15, 2024 (KR) 10-2024-0036576

(51) Int. Cl. H10K 59/80; G02B 27/01; H10H 29/37; H10H 29/80; H10H 29/85; H10K 59/122; H10K 59/38

(52) U.S. Cl. CPC H10K 59/877; G02B 27/0172; H10H 29/37; H10H 29/8517; H10H 29/882; H10K 59/122; H10K 59/38; G02B 2027/0178

(57) ABSTRACT

An embodiment provides a display device including a light functional layer disposed on a substrate, the light functional layer includes a bank having openings, a first light scattering pattern, a first sub-light conversion pattern, a second light scattering pattern, and a second sub-light conversion pattern sequentially disposed in a first opening of the openings, and a thickness of each of the first sub-light conversion pattern and the second sub-light conversion pattern is thicker than a thickness of the first light scattering pattern and the second light scattering pattern.

### CROSS-REFERENCE TO RELATED APPLICATION(S)

This application claims priority to and benefits of Korean Patent Application No. 10-2024-0036576 under 35 U.S.C. § 119 filed on Mar. 15, 2024 in the Korean Intellectual Property Office, the entire contents of which are incorporated herein by reference.

### BACKGROUND

### 1. Technical Field

The disclosure relates to a display device and a display system including the same.

### 2. Description of the Related Art

As information technology develops, the importance of display devices, which are a connection medium between users and information, is emerging. Accordingly, the use of display devices such as liquid crystal display devices, organic light emitting display devices, and inorganic light emitting display devices is increasing.

The display devices may convert a color of light outputted from a light emitting element. Methods that increase conversion efficiency may be needed.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

An object of the disclosure is to provide a display device with improved light conversion efficiency and a display system including the same.

A display device may include a light functional layer disposed on a substrate, wherein the light functional layer includes a bank having a plurality of openings, a first light scattering pattern, a first sub-light conversion pattern, a second light scattering pattern, and a second sub-light conversion pattern sequentially disposed in a first opening of the plurality of openings, and a thickness of each of the first sub-light conversion pattern and the second sub-light conversion pattern is thicker than a thickness of the first light scattering pattern and the second light scattering pattern.

The display device may further include a display element layer disposed between the substrate and the light functional layer, wherein the display element layer may include a first light emitting element, a second light emitting element and a third light emitting element respectively corresponding to a first sub-pixel, a second sub-pixel and a third sub-pixel, the first light scattering pattern may scatter first reference light emitted from the first light emitting element to provide a first sub-light conversion pattern, the first sub-light conversion pattern may convert a color of first light that is a portion of the first reference light, and the second light scattering pattern may provide second light that is a remainder of the first reference light to the first sub-light conversion pattern and the second sub-light conversion pattern.

The second light may be light of color not converted by the first sub-light conversion pattern.

The second light scattering pattern may provide first sub-light that is a portion of the second light to the first sub-light conversion pattern, and may provide second sub-light that is a remainder of the second light to the second sub-light conversion pattern.

The second sub-light conversion pattern may convert a color of the second sub-light.

The second sub-light conversion pattern may convert a color of light of the first sub-light that is not converted by the first sub-light conversion pattern.

A first light scattering pattern, a first sub-light conversion pattern, a second light scattering pattern, and a second sub-light conversion pattern may be sequentially disposed in a second opening of the plurality of openings, and the first opening may correspond to the first sub-pixel, the second opening may correspond to the second sub-pixel, and thicknesses of the first light scattering pattern and the second light scattering pattern disposed in the first opening may be different from thicknesses of the first light scattering pattern and the second light scattering pattern disposed in the second opening.

Thicknesses of the first sub-light conversion pattern and the second sub-light conversion pattern disposed in the first opening may be different from thicknesses of the first sub-light conversion pattern and the second sub-light conversion pattern disposed in the second opening.

A passivation layer may be disposed on the bank and the second sub-light conversion pattern.

A low refractive index layer may be disposed on the passivation layer.

The bank may include a first sub-bank and a second sub-bank disposed on the first sub-bank, a width of the first sub-bank in a first direction may be greater than a width of the second sub-bank in the first direction, and the first direction may be a direction in which the first to third sub-pixels are disposed.

A number of scattering particles included in the first light scattering pattern may be less than a number of scattering particles included in the second light scattering pattern.

A refractive index of the first light scattering pattern may be about 1.5 or less, and a refractive index of the second light scattering pattern may be about 1.5 or more.

Thicknesses of the first light scattering pattern, the first sub-light conversion pattern, the second light scattering pattern, and the second sub-light conversion pattern may be different.

An embodiment may include a display device including a light functional layer disposed on a substrate, wherein the light functional layer includes a bank having a plurality of openings, a first sub-light conversion pattern, a light scattering pattern, and a second sub-light conversion pattern are sequentially disposed in a first opening of the plurality of openings, and a thickness of each of the first sub-light conversion pattern and the second sub-light conversion pattern is thicker than a thickness of the light scattering pattern.

The display device may further include a display element layer disposed between the substrate and the light functional layer, wherein the display element layer may include a first light emitting element, a second light emitting element and a third light emitting element respectively corresponding to first sub-pixel, the second sub-pixel and a third sub-pixel, the first sub-light conversion pattern may convert a color of first light that is a portion of first reference light emitted from the first light emitting element, and the light scattering pattern may provide second light that is a remainder of a first reference light to the first sub-light conversion pattern and the second sub-light conversion pattern.

The second light may be light of color not converted by the first sub-light conversion pattern.

The light scattering pattern may provide first sub-light that is a portion of the second light to the first sub-light conversion pattern, and may provide the second sub-light that is a remainder of the second light to the second sub-light conversion pattern.

The second sub-light conversion pattern may convert a color of light of the second sub-light and the first sub-light that is not converted by the first sub light conversion pattern.

An embodiment may include a processor that provides image data and a control signal; and a display device including a display panel to display an image corresponding to the image data in response to the control signal, wherein the display panel includes a light functional layer disposed on a substrate, and the light functional layer includes a bank having a plurality of openings; a first light scattering pattern, a first sub-light conversion pattern, a second light scattering pattern, and a second sub-light conversion pattern sequentially disposed in a first opening of the plurality of openings; and a thickness of each of the first sub-light conversion pattern and the second sub-light conversion pattern is thicker than a thickness of the first light scattering pattern and the second light scattering pattern.

The display device may return light whose color is not converted, thereby improving light conversion efficiency and reducing power consumption.

### BRIEF DESCRIPTION OF THE DRAWINGS

The above and other aspects and features of the disclosure will become more apparent by describing in detail embodiments thereof with reference to the attached drawings, in which:

FIG. 1 illustrates a block diagram of a display device according to an embodiment.

FIG. 2 illustrates a block diagram of one of sub-pixels of FIG. 1 according to an embodiment.

FIG. 3 illustrates a schematic top plan view of a display panel of FIG. 1 according to an embodiment.

FIG. 4 illustrates a schematic cross-sectional view of a display panel of FIG. 3 according to an embodiment.

FIG. 5 illustrates a schematic cross-sectional view of a display panel of FIG. 3 according to an embodiment.

FIG. 6 illustrates a schematic top plan view of one of pixels of FIG. 3 according to an embodiment.

FIG. 7 illustrates a schematic cross-sectional view taken along line I-I′ of FIG. 6.

FIG. 8 illustrates a schematic cross-sectional view of a light functional layer of FIG. 7 according to an embodiment.

FIG. 9 illustrates a schematic cross-sectional view of a light functional layer of FIG. 7 according to an embodiment.

FIG. 10 illustrates a schematic cross-sectional view of a light functional layer of FIG. 7 according to an embodiment.

FIG. 11 illustrates a block diagram of a display system according to an embodiment.

FIG. 12 to FIG. 15 illustrate schematic perspective views of application examples of the display system of FIG. 11.

### DETAILED DESCRIPTION OF THE EMBODIMENTS

Hereinafter, embodiments will be described in detail with reference to the accompanying drawings. The following description is intended to provide a disclosure to enable the understanding, and any other disclosure may be omitted to avoid obscuring the scope of the disclosure. The disclosure may be embodied in different forms and is not limited to the embodiments set forth herein. The embodiments described herein are provided for the purpose of describing the disclosure in sufficient detail for those skilled in the art to readily practice the disclosure.

Throughout the specification, when it is described that an element is “connected” to another element, this includes not only being “directly connected”, but also being “indirectly connected” with another device in between. The terms used herein are for the purpose of describing embodiments and are not intended to limit the scope of the disclosure.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Throughout the specification, unless explicitly described to the contrary, the terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms first, second, etc. may be used herein to describe various constituent elements, these constituent elements should not be limited by these terms. These terms are used to distinguish one constituent element from another. Thus, a first constituent element discussed below could be termed a second constituent element without departing from the teachings of the disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

Various embodiments are described herein with reference to sectional illustrations that are schematic illustrations of given embodiments. As such, variations from the shapes of the illustrations as a result, for example, of manufacturing techniques and/or tolerances, are to be expected. Thus, embodiments disclosed herein should not be construed as limited to the illustrated shapes of regions, but are to include deviations in shapes that result from, for instance, manufacturing. Thus, the regions illustrated in the drawings are schematic in nature and their shapes are not intended to illustrate the actual shape of a region of a device and are not intended to be limiting.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

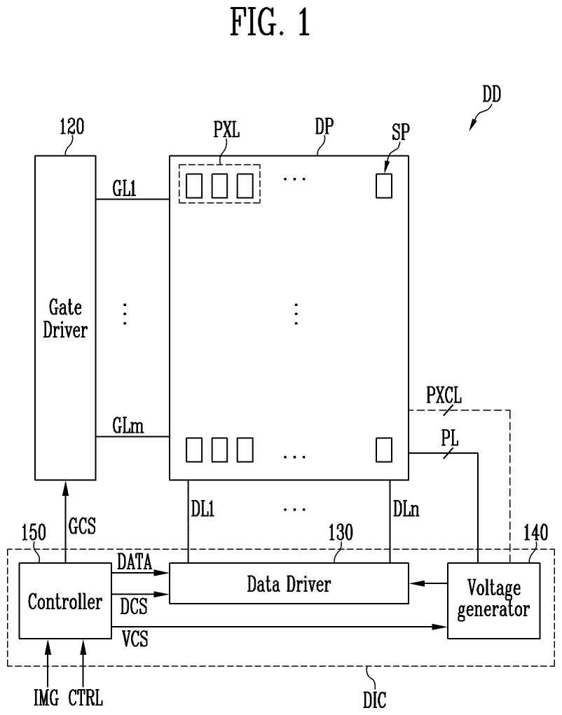

FIG. 1 illustrates a block diagram of a display device according to an embodiment.

Referring to FIG. 1, a display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate light of two or more colors. For example, the sub-pixels SP may respectively generate light of a color, such as red, green, blue, cyan, magenta, yellow, or the like within the spirit and the scope of the disclosure.

Two or more of the sub-pixels SP may configure one pixel PXL. For example, the pixel PXL may include three sub-pixels as shown in FIG. 1. As such, the pixel PXL may emit light of various colors and various luminance depending on a combination of light emitted from the sub-pixels included therein.

The gate driver 120 may be connected to the sub-pixels SP arranged (or disposed) in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating the start of each frame, a horizontal synchronization signal, and the like within the spirit and the scope of the disclosure.

The gate driver 120 may be disposed on one side or a side of the display panel DP. However, embodiments are not limited thereto. For example, the gate driver 120 may be divided into two or more physically and/or logically separated drivers, and the drivers may be disposed on one side or a side of the display panel DP and the other side of the display panel DP opposite to the one side or the side. As described above, the gate driver 120 may be disposed around the display panel DP in various forms according to the embodiments.

The data driver 130 may be connected to the sub-pixels SP arranged in a column direction through the first to n-th data lines DL1 to DLn. The data driver 130 receives image data (DATA) and data control signal DCS from the controller 150. The data driver 130 operates in response to the data control signal DCS. In embodiments, the data control signal DCS may include a source start signal, a source shift clock, a source output enable signal, and the like within the spirit and the scope of the disclosure.

The data driver 130 may receive voltages from the voltage generator 140. The data driver 130 may use the received voltages to apply data signals having grayscale voltages corresponding to the image data (DATA) to the first to n-th data lines DL1 to DLn. In case that a gate signal is applied to each of the first to m-th gate lines GL1 to GLn, data signals corresponding to the image data DATA may be applied to the data lines DL1 to DLm. Accordingly, the sub-pixels SP may generate light corresponding to the data signals, and the display panel DP may display an image.

In an embodiment, the gate driver 120 and the data driver 130 may include complementary metal-oxide semiconductor (CMOS) circuit elements.

The voltage generator 140 may operate in response to a voltage control signal VCS from the controller 150. The voltage generator 140 is configured to generate voltages and provide the generated voltages to components of the display device DD, such as the gate driver 120, the data driver 130, and the controller 150. The voltage generator 140 may generate voltages by receiving an input voltage from the outside of the display device DD and regulating the received voltage.

The voltage generator 140 may generate a first power voltage and a second power voltage. The generated first and second power voltages may be provided to the sub-pixels SP through the power lines PL. In other embodiments, at least one of the first and second power voltages may be provided from the outside of the display device DD.

The voltage generator 140 may provide various voltages and/or signals. For example, the voltage generator 140 may provide one or more initialization voltages applied to the sub-pixels SP. For example, during a sensing operation to sense electrical characteristics of transistors and/or light emitting elements of the sub-pixels SP, a selectable reference voltage may be applied to the first to n-th data lines DL1 to DLn, and the voltage generator 140 may generate the reference voltage to transmit it to the data driver 130. For example, during a display operation for displaying an image on the display panel DP, common pixel control signals may be applied to the sub-pixels SP, and the voltage generator 140 may generate the pixel control signals. In embodiments, the voltage generator 140 may provide pixel control signals to the sub-pixels SP through a pixel control lines PXCL. FIG. 1 illustrates that the pixel control lines PXCL are connected between the voltage generator 140 and the display panel DP, but the embodiments are not limited thereto. For example, the pixel control lines PXCL may be connected between the gate driver 120 and the display panel DP. In this case, the pixel control signals may be transmitted from the voltage generator 140 to the pixel control lines PXCL through the gate driver 120.

The controller 150 controls various operations of the display device DD. The controller 150 receives input image data IMG and a control signal CTRL corresponding thereto, from the outside. The controller 150 may provide the gate control signal GCS, the data control signal DCS, and the voltage control signal VCS in response to the control signal CTRL.

The controller 150 may convert the input image data IMG to be suitable for the display device DD or the display panel DP to output the image data DATA. In embodiments, the controller 150 may output the image data DATA by aligning the input image data IMG to be suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally separate components within or in one driver integrated circuit DIC. In other embodiments, at least one of the data driver 130, the voltage generator 140, and the controller 150 may be provided as a component separated from the driver integrated circuit DIC.

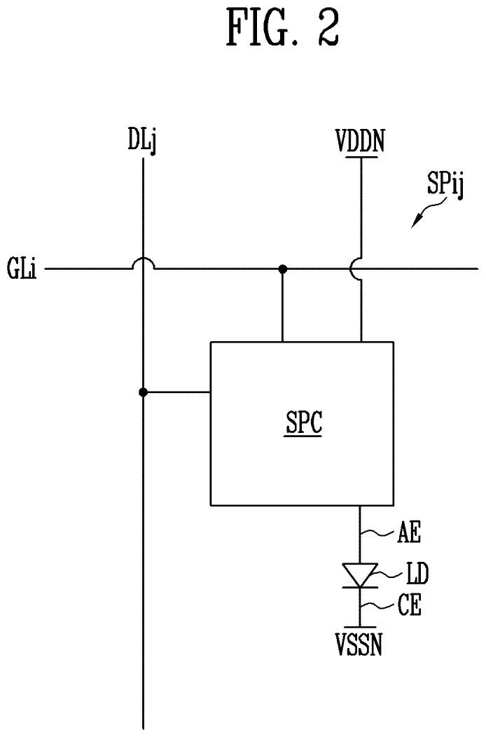

FIG. 2 illustrates a block diagram of one of sub-pixels of FIG. 1 according to an embodiment. In FIG. 2, among the sub-pixels SP of FIG. 1, a sub-pixel SPij disposed in an i-th row (i is an integer greater than or equal to 1 and less than or equal to m) and a j-th column (j is an integer greater than or equal to 1 and less than or equal to n) is illustrated as an example.

Referring to FIG. 2, the sub-pixel SPij may include a sub-pixel circuit SPC and a light emitting element LD.

The light emitting element LD may be connected between the first power voltage node VDDN and a second power voltage node VSSN. The first power voltage node VDDN may be connected to one of the power lines PL in FIG. 1 to receive the first power voltage. The second power voltage node VSSN may be connected to another one of the power lines PL in FIG. 1 to receive the second power voltage. The first power voltage may have a higher voltage level than the second power voltage.

The light emitting element LD may be connected between the anode electrode AE and the cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light emitting element LD is configured to emit light according to a current flowing from the anode electrode AE to the cathode electrode CE.

The sub-pixel circuit SPC may be connected to an i-th gate line GLi of the first to m-th gate lines GL1 to GLm of FIG. 1 and a j-th data line DLj of the first to n-th data lines DL1 to DLn of FIG. 1. In response to the gate signal received through the i-th gate line GLi, the sub-pixel circuit SPC controls the light emitting element LD to emit light according to the data signal received through the j-th data line DLj. In embodiments, the sub-pixel circuit SPC may be further connected to the pixel control lines PXCL of FIG. 1. In this case, the sub-pixel circuit SPC may control the light emitting element LD in further response to pixel control signals received through the pixel control lines PXCL.

For these operations, the sub-pixel circuit SPC may include circuit elements, for example transistors and one or more capacitors.

The transistors of the sub-pixel circuit SPC may include P-type transistors and/or N-type transistors. In embodiments, the transistors of the sub-pixel circuit SPC may include a metal oxide silicon field effect transistor (MOSFET). In embodiments, the transistors of the sub-pixel circuit SPC may include an amorphous silicon semiconductor, a monocrystalline silicon semiconductor, a polycrystalline silicon semiconductor, and an oxide semiconductor.

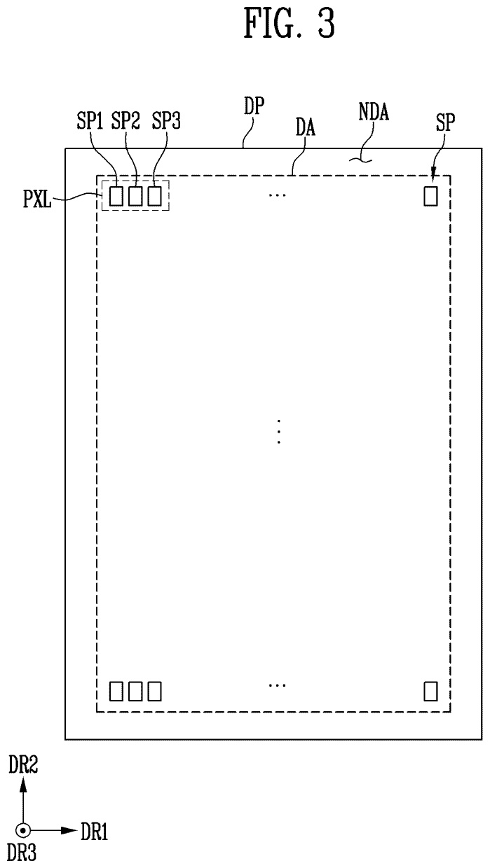

FIG. 3 illustrates a schematic top plan view of a display panel of FIG. 1 according to an embodiment.

Referring to FIG. 3, the display panel DP may include a display area DA and a non-display area NDA. The display panel DP displays an image through the display area DA. The non-display area NDA is disposed around the display area DA.

The display panel DP may include sub-pixels SP in the display area DA. The sub-pixels SP may be arranged along a first direction DR1 and a second direction DR2 that intersects the first direction DR1. For example, the sub-pixels SP may be arranged in a matrix format along the first direction DR1 and the second direction DR2. As another example, the sub-pixels SP may be arranged in a zigzag form along first direction DR1 and second direction DR2. The arrangement of the sub-pixels SP may vary in an embodiment. The first direction DR1 may be a row direction, and the second direction DR2 may be a column direction.

Two or more of the sub-pixels SP may configure one pixel PXL. FIG. 3 illustrates that the pixel PXL may include three sub-pixels SP1 to SP3, but embodiments are not limited thereto. For example, the pixel PXL may include two sub-pixels. Hereinafter, for better understanding and ease of description, it is assumed that the pixel PXL may include the first to third sub-pixels SP1 to SP3.

Each of the first to third sub-pixels SP1 to SP3 may generate one of various colors such as red, green, blue, cyan, magenta, and yellow. Hereinafter, for clear and brief description, it is assumed that the first sub-pixel SP1 is configured to generate red-colored light, the second sub-pixel SP2 is configured to generate green-colored light, and the third sub-pixel SP3 is configured to generate blue-colored light.

Each of the first to third sub-pixels SP1 to SP3 may include at least one light emitting element configured to generate light. In embodiments, the light emitting elements of the first to third sub-pixels SP1 to SP3 may generate light of the same color. For example, the light emitting elements of the first to third sub-pixels SP1 to SP3 may generate blue-colored light. In other embodiments, the light emitting elements of the first to third sub-pixels SP1 to SP3 may generate light of different colors. For example, the light emitting elements of the first to third sub-pixels SP1 to SP3 may generate light of red, green, and blue colors, respectively.

As the display panel DP, a self-luminous display panel such as an LED display panel using a micro-scale or nano-scale light emitting diode as a light emitting element and an organic light emitting display panel using an organic light emitting diode as a light emitting element may be used.

A constituent element to control the sub-pixels SP may be disposed in the non-display area NDA. Wires connected to the sub-pixels SP, for example, the first to m-th gate lines GL1 to GLm, the first to n-th data lines DL1 to DLn, the power lines PL, and the pixel control lines PXCL shown in FIG. 1 may be disposed in the non-display area NDA.

At least one of the gate driver 120, the data driver 130, the voltage generator 140, and the controller 150 in FIG. 1 may be disposed in the non-display area NDA of the display panel DP. In the embodiment, the gate driver 120 may be disposed in the non-display area NDA. In this case, the data driver 130, the voltage generator 140, and the controller 150 may be implemented as the driver integrated circuit DIC of FIG. 1 separated from the display panel DP, and the driver integrated circuit DIC may be connected to wires disposed in the non-display area NDA. In other embodiments, the gate driver 120 may be implemented as one integrated circuit separated from the display panel DP together with the data driver 130, the voltage generator 140, and the controller 150.

In embodiments, the display area DA may have various shapes. The display area DA may have a closed-loop shape including sides of a straight line and/or a curved line. For example, the display area DA may have shapes such as a polygonal shape, a circular shape, a semicircular, and an elliptical shape.

In embodiments, the display panel DP may have a flat display surface. In other embodiments, the display panel DP may have a display surface that is at least partially round. In embodiments, the display panel DP may be bendable, foldable, or rollable. In these cases, the display panel DP and/or the substrate of the display panel DP may include materials with flexible properties.

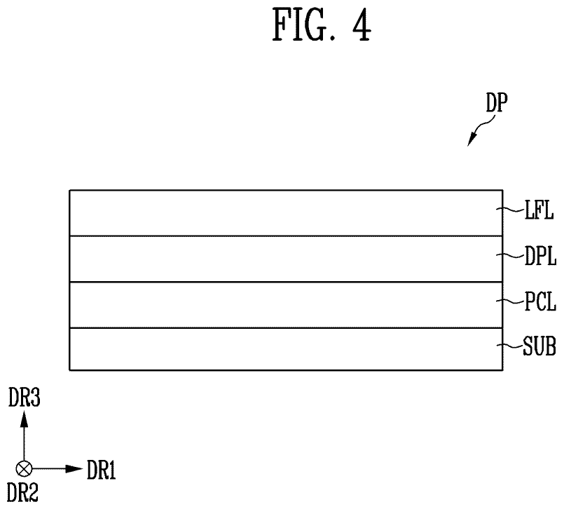

FIG. 4 illustrates a schematic cross-sectional view of a display panel of FIG. 3 according to an embodiment.

Referring to FIG. 4, the display panel DP may include a substrate SUB, and a pixel circuit layer PCL, a display element layer DPL, and a light functional layer LFL, which are sequentially stacked on the substrate SUB in a third direction DR3 crossing (or intersecting) the first and second directions DR1 and DR2.

The substrate SUB may be made of an insulating material such as glass or a resin. For example, the substrate SUB may include a glass substrate. As another example, the substrate SUB may include a polyimide (PI) substrate. As another example, the substrate SUB may include a silicon wafer substrate formed using a semiconductor process.

In embodiments, the substrate SUB may be made of a flexible material to be bendable or foldable, and may have a single-layered structure or a multi-layered structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL is disposed on the substrate SUB. The pixel circuit layer PCL may include insulating layers and semiconductor patterns and conductive patterns disposed between the insulating layers. The conductive patterns of the pixel circuit layer PCL may function as circuit elements, wires, and the like within the spirit and the scope of the disclosure.

The circuit elements of the pixel circuit layer PCL may include the sub-pixel circuit SPC (see FIG. 2) of each of the sub-pixels SP of FIG. 3. In other words, the circuit elements of the pixel circuit layer PCL may be provided as transistors and one or more capacitors of the sub-pixel circuit SPC.

The wires of the pixel circuit layer PCL may include wires connected to the sub-pixels SP. The wires of the pixel circuit layer PCL may include various signal lines and/or voltage lines required to drive the display element layer DPL.

The display element layer DPL is disposed on the pixel circuit layer PCL. The display element layer DPL may include light emitting elements of the sub-pixels SP.

The light functional layer LFL may be disposed on the display element layer DPL. The light functional layer LFL may include light conversion patterns having color conversion particles and/or scattering particles. For example, the color conversion particles may include quantum dots. The quantum dots may change the wavelength (or color) of light emitted from the display element layer DPL. The light functional layer LFL may further include light scattering patterns with scattering particles. In embodiments, the light conversion patterns and the light scattering patterns may be omitted.

The light functional layer LFL may further include a color filter layer including color filters. The color filter may selectively transmit light of a given wavelength (or a given color). In embodiments, the color filter layer may be omitted.

A window for protecting an exposed surface (or upper surface) of the display panel DP may be provided on the light functional layer LFL. The window may protect the display panel DP from external impact. The window may be coupled or connected to the light functional layer LFL through an optically transparent adhesive (bonding) member. The window may have a multi-layered structure selected from a glass substrate, a plastic film, and a plastic substrate. The multi-layered structure may be formed through a continuous process or an adhesive process using an adhesive layer. All or a portion of the window may be flexible.

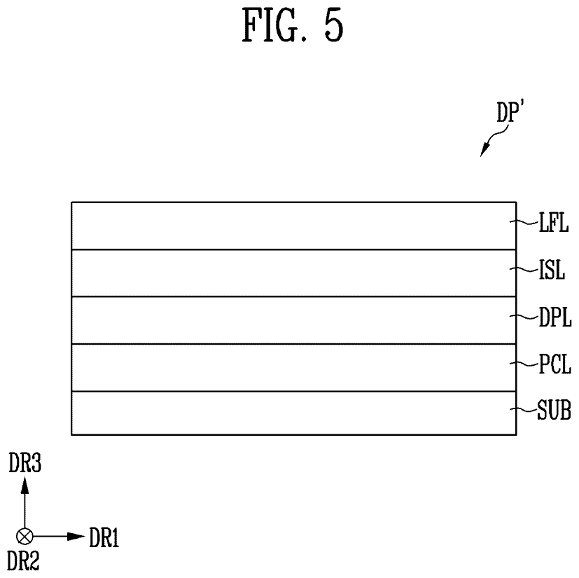

FIG. 5 illustrates a schematic cross-sectional view of a display panel of FIG. 3 according to an embodiment.

Referring to FIG. 5, a display panel DP' may include a substrate SUB, a pixel circuit layer PCL, a display element layer DPL, an input sensing layer ISL, and a light functional layer LFL. The substrate SUB, the pixel circuit layer PCL, the display element layer DPL, and the light functional layer LFL are configured in the same manner as the substrate SUB, the pixel circuit layer PCL, the display element layer DPL, and the light functional layer LFL described with reference to FIG. 4. Hereinafter, redundant descriptions thereof will be omitted.

The input sensing layer ISL may detect a user input on an upper surface (or display surface) of the display panel DP′. The input sensing layer ISL may include components suitable for sensing an external object such as a user's hand or pen. For example, the input sensing layer ISL may include touch electrodes.

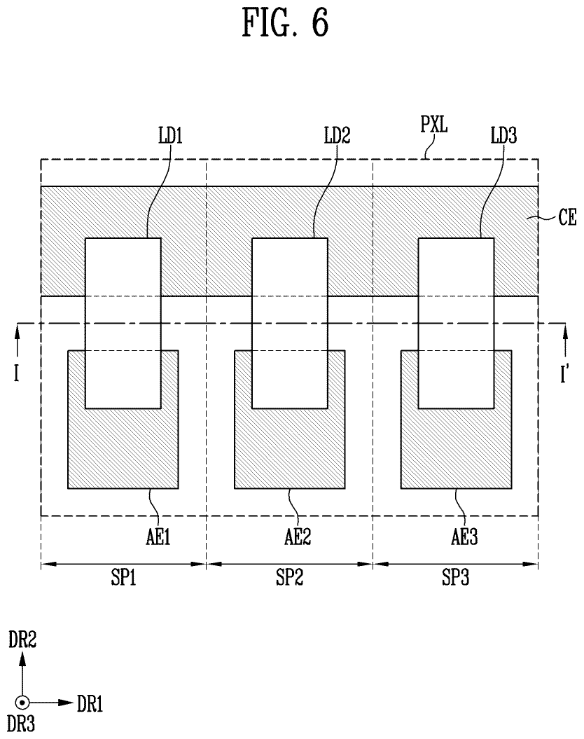

FIG. 6 illustrates a schematic top plan view of one of pixels of FIG. 3 according to an embodiment.

Referring to FIG. 6, the pixel PXL may include the first to third sub-pixels SP1 to SP3. The first to third sub-pixels SP1 to SP3 may be arranged in the first direction DR1. However, the arrangement of pixels PXL is not limited thereto, and may be variously changed in an embodiment. For example, the first to third sub-pixels SP1 to SP3 may be arranged in a zigzag pattern.

First to third anode electrodes AE1 to AE3 may be disposed in the first to third sub-pixels SP1 to SP3, respectively. The first anode electrode AE1 may be provided as the anode electrode AE (see FIG. 2) connected to the sub-pixel circuit SPC (see FIG. 2) of the first sub-pixel SP1. The second anode electrode AE2 may be provided as the anode electrode AE connected to the sub-pixel circuit SPC of the second sub-pixel SP2. The third anode electrode AE3 may be provided as the anode electrode AE connected to the sub-pixel circuit SPC of the third sub-pixel SP3.

The cathode electrode CE may be spaced apart from the first to third anode electrodes AE1 to AE3. The cathode electrode CE may be disposed at the same height as the first to third anode electrodes AE1 to AE3. The cathode electrode CE may be spaced apart from the first to third anode electrodes AE1 to AE3 in the second direction DR2. In embodiments, the cathode electrode CE may extend in the first direction DR1 and be used as a common electrode for the pixel PXL and other pixels adjacent to the pixel PXL. Although not shown, the cathode electrode CE extends not only in the first direction DR1 but also in the second direction DR2 and may be used as a common electrode for all of the sub-pixels SP of FIG. 3. As such, the cathode electrode CE may have various shapes.

First to third light emitting elements LD1 to LD3 may be disposed on the first to third anode electrodes AE1 to AE3 and the cathode electrode CE. The first light emitting element LD1 may be electrically connected to the first anode electrode AE1 and the cathode electrode CE. The first light emitting element LD1 may be provided as the light emitting element LD (see FIG. 2) connected to the sub-pixel circuit SPC of the first sub-pixel SP1. The second light emitting element LD2 may be electrically connected to the second anode electrode AE2 and the cathode electrode CE. The second light emitting element LD2 may be provided as the light emitting element LD connected to the sub-pixel circuit SPC of the second sub-pixel SP2. The third light emitting element LD3 may be electrically connected to the third anode electrode AE3 and the cathode electrode CE. The third light emitting element LD3 may be provided as the light emitting element LD connected to the sub-pixel circuit SPC of the third sub-pixel SP3.

The first light emitting element LD1, the second light emitting element LD2, and the third light emitting element LD3 may be inorganic light emitting diodes containing an inorganic light emitting material. However, embodiments are not limited thereto and, for example, organic light emitting diodes may be used.

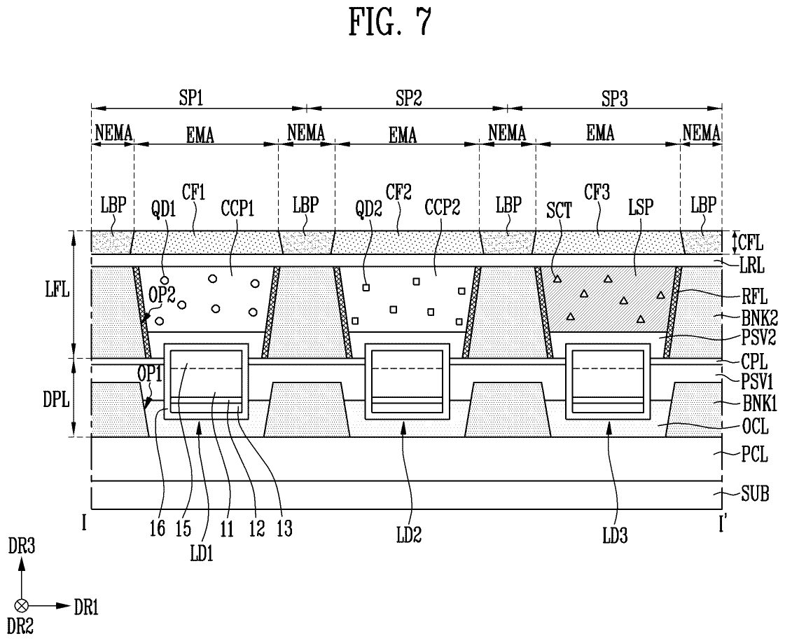

FIG. 7 illustrates a schematic cross-sectional view taken along line I-I′ of FIG. 6.

Referring to FIG. 6 and FIG. 7, the pixel circuit layer PCL, the display element layer DPL, and the light functional layer LFL may be sequentially disposed on the substrate SUB.

In the pixel circuit layer PCL, sub-pixel circuits corresponding to the first to third sub-pixels SP1 to SP3 are provided.

As described with reference to FIG. 2, the sub-pixel circuit SPC (see FIG. 2) of each of the first to third sub-pixels SP1 to SP3 may include transistors and one or more capacitors. The semiconductor patterns and conductive patterns of the pixel circuit layer PCL may function as transistors and capacitors of the sub-pixel circuit SPC. The conductive patterns of the pixel circuit layer PCL may further function as wires, for example, the first to m-th gate lines GL1 to GLm, the first to n-th data lines DL1 to DLn, the power lines PL, and the pixel control lines PXCL in FIG. 1.

The display element layer DPL may be disposed on the pixel circuit layer PCL.

The display element layer DPL may include the first to third anode electrodes AE1 to AE3 (see FIG. 6), the cathode electrode CE (see FIG. 6), a first bank BNK1, and the first to third light emitting elements LD1 to LD3, an overcoat layer OCL, a first passivation layer PSV1, and a capping layer CPL.

The first to third light emitting elements LD1 to LD3 may respectively correspond to the first to third sub-pixels SP1 to SP3 disposed on the pixel circuit layer PCL. By way of non-limiting example, the first light emitting element LD1 may be connected between the cathode electrode CE and the transistor included in the sub-pixel circuit of the first sub-pixel SP1. The second light emitting element LD2 may be connected between the cathode electrode CE and the transistor included in the sub-pixel circuit of the second sub-pixel SP2. The third light emitting element LD3 may be connected between the cathode electrode CE and the transistor included in the sub-pixel circuit of the third sub-pixel SP3.

The first bank BNK1 may be disposed on the first to third anode electrodes AE1 to AE3 and the cathode electrode CE. The first bank BNK1 may have first openings OP1 exposing portions of the first to third anode electrodes AE1 to AE3 and the cathode electrode CE.

The first to third light emitting elements LD1 to LD3 may overlap the first openings OP1 of the first bank BNK1. For example, each of the first to third light emitting elements LD1 to LD3 may be disposed in each of the first openings OP1 of the first bank BNK1. In this way, the first bank BNK1 may be provided as a pixel defining film that defines an area in which the first to third light emitting elements LD1 to LD3 are disposed.

The first bank BNK1 is configured to include a light-blocking material, thereby preventing light mixing between adjacent sub-pixels. In embodiments, the first bank BNK1 may include an organic material. For example, the first bank BNK1 may include an organic insulating material such as an acrylic resin, an epoxy resin, a phenol resin, a polyamide resin, a polyimide resin, or the like within the spirit and the scope of the disclosure.

The first light emitting element LD1 may include a first semiconductor layer 11, an active layer 12, a second semiconductor layer 13, and an auxiliary layer 15. The first light emitting element LD1 may include a light emitting stack in which the auxiliary layer 15, the first semiconductor layer 11, the active layer 12, and the second semiconductor layer 13 may be sequentially stacked each other.

The first semiconductor layer 11 is configured to provide electrons to the active layer 12. For example, the first semiconductor layer 11 may include at least one n-type semiconductor layer. For example, the first semiconductor layer 11 may include one of gallium nitride (GaN), aluminum gallium nitride (AlGaN), indium gallium nitride (InGaN), aluminum nitride (AlN), and indium nitride (InN), and may be an n-type semiconductor layer doped with a first conductive dopant (or n-type dopant) such as silicon (Si), germanium (Ge), tin (Sn), and the like within the spirit and the scope of the disclosure. However, the material included in the first semiconductor layer 11 is not limited thereto, and the first semiconductor layer 11 may be made of various materials. In the embodiment, the first semiconductor layer 11 may include a gallium nitride (GaN) semiconductor material doped with the first conductive dopant (or n-type dopant). In an embodiment, the first semiconductor layer 11 may form an n-type semiconductor layer together with the auxiliary layer 15.

The active layer 12 is disposed on the first semiconductor layer 11, and it may be an area in which electrons and holes are recombined. As the electrons and holes are recombined in the active layer 12, they transit to a low energy level, and accordingly, light having a wavelength corresponding thereto may be generated. The active layer 12 may have a single or multiple quantum well structure. In case that the active layer 12 is formed in a multi-quantum well structure, units including a barrier layer, a strain reinforcing layer, and a well layer may be repeatedly stacked to form the active layer 12. However, embodiments of the active layer 12 are not limited thereto.

The second semiconductor layer 13 is disposed on the active layer 12, and provides a hole in the active layer 12. The second semiconductor layer 13 may include a semiconductor layer of a type different from that of the first semiconductor layer 11. For example, the second semiconductor layer 13 may include at least one p-type semiconductor layer. For example, the second semiconductor layer 13 may include at least one of gallium nitride (GaN), aluminum gallium nitride (AlGaN), indium gallium nitride (InGaN), aluminum nitride (AlN), and indium nitride (InN), and may be a p-type semiconductor layer doped with a second conductive dopant (or p-type dopant) such as magnesium (Mg), zinc (Zn), calcium (Ca), strontium (Sr), barium (Ba), and the like within the spirit and the scope of the disclosure. However, the material included in the second semiconductor layer 13 is not limited thereto, and the second semiconductor layer 13 may be formed of various materials. In the embodiment, the second semiconductor layer 13 may include a gallium nitride (GaN) semiconductor material doped with the second conductive dopant (or p-type dopant).

The auxiliary layer 15 may include a gallium nitride (GaN) semiconductor material that is not doped with impurities, and may form an n-type semiconductor layer together with the first semiconductor layer 11.

The first light emitting element LD1 may further include an insulating film 16 covering the outer peripheral surface of the light emitting stack. The insulating film 16 may prevent an electrical short circuit that may occur in case that the active layer 12 contacts other conductive materials other than the first and second semiconductor layers 11 and 13. The insulating film 16 may include a transparent insulating material.

The overcoat layer OCL may be disposed in the first openings OP1. The overcoat layer OCL may fix the first to third light emitting elements LD1 to LD3 so that they do not move. The overcoat layer OCL may protect components disposed thereunder from foreign substances such as dust and moisture. For example, the overcoat layer OCL may include at least one of an inorganic insulating film and an organic insulating film. For example, the overcoat layer OCL may include an epoxy resin, but embodiments are not limited thereto.

The first passivation layer PSV1 is disposed on the first bank BNK1 and the overcoat layer OCL. The first passivation layer PSV1 may protect components disposed thereunder, and may provide a flat upper surface. The first passivation layer PSV1 may include an inorganic insulating layer containing an inorganic material and/or an organic insulating layer containing an organic material. The inorganic insulating layer may include, for example, at least one of metal oxides such as a silicon oxide (SiOₓ), a silicon nitride (SiNₓ), a silicon nitride (SiOₓN_{y}), and an aluminum oxide (AlOₓ). The organic insulating layer may include at least one of, for example, an acrylic resin, an epoxy resin, a phenol resin, a polyamide resin, a polyimide resin, an unsaturated polyester resin, a poly-phenylene ether resin, a poly-phenylene sulfide resin, and a benzocyclobutene resin.

The first passivation layer PSV1 may be provided as a single layer, but may also be provided as a multilayer.

In embodiments, the first passivation layer PSV1 may not be disposed on the upper surfaces of the first to third light emitting elements LD1 to LD3. The first to third light emitting elements LD1 to LD3 may protrude into the light functional layer LFL. The first to third light emitting elements LD1 to LD3 may be disposed at least partially in the second opening OP2 of the second bank BNK2. Accordingly, the light emitted from the first light emitting element LD1 may be provided to the light functional layer LFL at a relatively high ratio.

The capping layer CPL is disposed on the first passivation layer PSV1. The capping layer CPL may protect components under or below the capping layer CPL, such as the first to third light emitting elements LD1 to LD3, from external moisture and humidity. In embodiments, the capping layer CPL may not be disposed on the upper surfaces of the first to third light emitting elements LD1 to LD3. In embodiments, the capping layer CPL may entirely cover the first to third light emitting elements LD1 to LD3 and the first passivation layer PSV1. The capping layer CPL may include at least one of metal oxides such as a silicon nitride (SiNₓ), a silicon oxide (SiOₓ), a silicon oxynitride (SiOₓN_{y}), and an aluminum oxide (AlOₓ). However, the material of the capping layer CPL is not limited thereto.

The light functional layer LFL is disposed on the capping layer CPL. The light functional layer LFL may include a second bank BNK2, a reflective layer RFL, a second passivation layer PSV2, a first light conversion pattern CCP1, a low refractive index layer LRL, and a color filter layer CFL.

The second bank BNK2 is disposed on the capping layer CPL. The second bank BNK2 may overlap the first bank BNK1. The second bank BNK2 may have second openings OP2 that overlap the first openings OP1. It may be understood that the light emitting area EMA and the non-light emitting area NEMA for the first to third sub-pixels SP1 to SP3 are defined by the second bank BNK2. An area where the second bank BNK2 overlaps may correspond to the non-light emitting area NEMA. An area overlapping the second openings OP2 of the second bank BNK2 may correspond to the light emitting area EMA of the first to third sub-pixels SP1 to SP3.

The second bank BNK2 may be configured to include a light blocking material to prevent light mixing between adjacent sub-pixels. In embodiments, the second bank BNK1 may include an organic material. For example, the second bank BNK2 may include an organic insulating material such as an acrylic resin, an epoxy resin, a phenol resin, a polyamide resin, a polyimide resin, or the like within the spirit and the scope of the disclosure.

The reflective layer RFL may be disposed on side surfaces of the second bank BNK2 adjacent to the second opening OP2. The reflective layer RFL is configured to reflect incident light, thereby improving outgoing light efficiency. The reflective layer RFL may include a material suitable for reflecting light. The reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected therefrom. However, embodiments are not limited thereto.

On the capping layer CPL, the second passivation layer PSV2 is disposed in the second opening OP2. The second passivation layer PSV2 may protect components disposed thereunder, and may provide a flat upper surface. The second passivation layer PSV2 may include a same material as the first passivation layer PSV1, but embodiments are not limited thereto.

On the second passivation layer PSV2, first and second light conversion patterns CCP1 and CCP2 and a light scattering pattern LSP may be disposed in the second opening OP2.

In embodiments, the first to third light emitting elements LD1 to LD3 may be configured to emit blue-colored light. In this case, the first light conversion pattern CCP1 may be disposed in the second opening OP2 corresponding to the first sub-pixel SP1. The first light conversion pattern CCP1 may include first color conversion particles QD1 configured to convert blue-colored light into red-colored light. The second light conversion pattern CCP2 may be disposed in the second opening OP2 corresponding to the second sub-pixel SP2. The second light conversion pattern CCP2 may include second color conversion particles QD2 configured to convert blue-colored light into green-colored light. In embodiments, the first and second color conversion particles QD1, and QD2 may be quantum dots. The light scattering pattern LSP may be disposed in the second opening OP2 corresponding to the third sub-pixel SP3. The light scattering pattern LSP may include scattering particles SCT that scatter blue-colored light in order to improve light output efficiency.

Accordingly, the first to third sub-pixels SP1 to SP3 may be provided as a red sub-pixel, a green sub-pixel, and a blue sub-pixel, respectively. In embodiments, at least one of the first and second light conversion patterns CCP1 and CCP2 and the light scattering pattern LSP may further include color conversion particles that convert blue-colored light into white-colored light.

In embodiments, the first to third light emitting elements LD1 to LD3 may be configured to emit red-colored, green-colored, and blue-colored light, respectively. In this case, each of the first and second light conversion patterns CCP1 and CCP2 and the light scattering pattern LSP may include the scattering particles SCT. As described above, the particles included in the first and second light conversion patterns CCP1 and CCP2 and the light scattering pattern LSP may be variously changed according to the first to third light emitting elements LD1 to LD3.

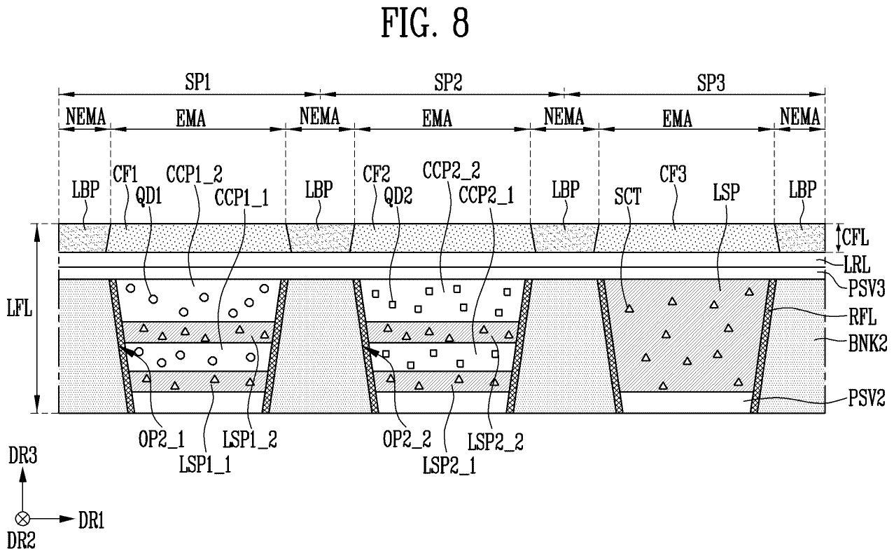

In embodiments, the first light scattering pattern LSP1_1, the first sub-light conversion pattern CCP1_1, the second light scattering pattern LSP1_2, and the second sub-light conversion pattern CCP1_2 may be sequentially disposed in the second opening OP2 corresponding to the first sub-pixel SP1. The first light scattering pattern LSP2_1, the first sub-light conversion pattern CCP2_1, the second light scattering pattern LSP2_2, and the second sub-light conversion pattern CCP2_2 may be sequentially disposed in the second opening OP2 corresponding to the second sub-pixel SP2. This will be described in more detail later with reference to FIG. 8.

The low refractive index layer LRL may be disposed on the second bank BNK2, the reflective layer RFL, the first light conversion pattern CCP1, the second light conversion pattern CCP2, and the light scattering pattern LSP. The low refractive index layer LRL may have a lower refractive index than that of the first and second light conversion patterns CCP1 and CCP2 and the light scattering pattern LSP. In embodiments, the low refractive index layer LRL may be omitted in an area corresponding to the third sub-pixel SP3.

In embodiments, a third passivation layer may be disposed on the second bank BNK2, the reflective layer RFL, the first light conversion pattern CCP1, the second light conversion pattern CCP2, and the light scattering pattern LSP, and the low refractive index layer LRL may be disposed on the third passivation layer. This will be described in more detail later with reference to FIG. 8.

The color filter layer CFL may be disposed on the low refractive index layer LRL. The color filter layer CFL may include first to third color filters CF1 to CF3 and light blocking patterns LBP.

Each of the first to third color filters CF1 to CF3 may selectively transmit light in a desired wavelength range. In case that the first sub-pixel SP1 is a red sub-pixel, the first color filter CF1 may include a red color filter. In case that the second sub-pixel SP2 is a green sub-pixel, the second color filter CF2 may include a green color filter. In case that the third sub-pixel SP3 is a blue sub-pixel, the third color filter CF3 may include a blue color filter. The first to third color filters CF1 to CF3 may have a higher refractive index than the low refractive index layer LRL. However, embodiments are not limited thereto, and the first to third color filters CF1 to CF3 may have a refractive index lower than or equal to that of the low refractive index layer LRL.

The light blocking patterns LBP may be disposed between the first to third color filters CF1 to CF3. It may be understood that the light emitting area EMA and the non-light emitting area NEMA for the first to third sub-pixels SP1 to SP3 are defined by the light blocking patterns LBP. An area overlapping the light blocking patterns LBP may correspond to the non-light emitting area NEMA. An area that does not overlap the light blocking patterns LBP may correspond to the light emitting area EMA.

In embodiments, the light blocking patterns LBP may include at least one of various types of light blocking materials. In embodiments, each of the light blocking patterns LBP may be provided in the form of a multilayer in which at least two of the first to third color filters CF1 to CF3 overlap. For example, each of the light blocking patterns LBP may be formed by overlapping the first to third color filters CF1 to CF3. As another example, among of the light blocking patterns LBP, a light blocking pattern between the first and second color filters CF1 and CF2 may be formed as a multilayer in which the first and second color filters CF1 and CF2 overlap, and among of the light blocking patterns LBP, a light blocking pattern between the second and third color filters CF2 and CF3 may be formed as a multilayer in which the second and third color filters CF2 and CF3 overlap. The light blocking pattern between the first color filter CF1 and the third color filter CF3 of a neighboring pixel may be formed as a multilayer in which the first and third color filters CF1 and CF3 overlap. In this way, each of the first to third color filters CF1 to CF3 may extend to the non-light emitting area NEMA to form the light blocking patterns LBP.

FIG. 8 illustrates a schematic cross-sectional view of a light functional layer of FIG. 7 according to an embodiment.

Referring to FIG. 7 and FIG. 8, the light functional layer LRL having a multilayer formed in second openings OP2_1 and OP2_2 corresponding to the first and second sub-pixels SP1 and SP2 is illustrated.

The first light scattering pattern LSP1_1, the first sub-light conversion pattern CCP1_1, the second light scattering pattern LSP1_2, and the second sub-light conversion pattern CCP1_2 may be sequentially disposed in the second opening OP2_1 corresponding to the first sub-pixel SP1.

The first and second light scattering patterns LSP1_1 and LSP1_2 may include scattering particles SCT that scatter blue-colored light in order to improve light output efficiency. The first and second sub-light conversion patterns CCP1_1 and CCP1_2 may include first color conversion particles QD1 configured to convert blue-colored light into red-colored light.

The number of scattering particles SCT included in the first light scattering pattern LSP1_1 may be smaller than the number of scattering particles SCT included in the second light scattering pattern LSP1_2. For example, the refractive index of the first light scattering pattern LSP1_1 may be about 1.5 or less, and the refractive index of the second light scattering pattern LSP1_2 may be about 1.5 or more.

The thickness of each of the first and second sub light conversion patterns CCP1_1 and CCP1_2 may be thicker than that of each of the first and second light scattering patterns LSP1_1 and LSP1_2. In the specification, the thickness may refer to a width in the third direction DR3.

The thicknesses of the first and second sub-light conversion patterns CCP1_1 and CCP1_2 and the first and second light scattering patterns LSP1_1 and LSP1_2 may be different from each other.

In embodiments, the sum of respective thicknesses of the first and second light scattering patterns LSP1_1 and LSP1_2 may be 30% or less of the sum of respective thicknesses of the first and second sub light conversion patterns CCP1_1 and CCP1_2, and the first and second light scattering patterns LSP1_1 and LSP1_2.

The first light scattering pattern LSP1_1 may scatter the first reference light emitted from the first light emitting element LD1 to provide the first reference light to the first sub-light conversion pattern CCP1_1.

The first sub-light conversion pattern CCP1_1 may convert the first light, which is a portion of the first reference light provided from the first light scattering pattern LSP1_1, into red colored light.

The second light scattering pattern LSP1_2 may scatter the second light, which is the remainder of the first reference light, to provide it to the second sub-light conversion pattern CCP1_2, or may recycle the second light to provide it to the first sub-light conversion pattern CCP1_1. The second light may be light that has not been converted by the first sub-light conversion pattern CCP1_1.

By way of non-limiting example, the second light scattering pattern LSP1_2 may provide the first sub-light, which is a portion of the second light, to the first sub-light conversion pattern CCP1_1, or the second sub-light, which is the remainder of the second light, to the second sub-light conversion pattern CCP1_2.

The first sub-light conversion pattern CCP1_1 may convert the first sub-light returned from the second light scattering pattern LSP1_2 into red colored light. The second sub-light conversion pattern CCP1_2 may convert the second sub-light into red-colored light.

In embodiments, the second sub-light conversion pattern CCP1_2 may convert light that is not converted by the first sub-light conversion pattern CCP1_1 among the first sub-light into red-colored light.

As the first light scattering pattern LSP1_1, the first sub-light conversion pattern CCP1_1, the second light scattering pattern LSP1_2, and the second sub-light conversion pattern CCP1_2 are sequentially disposed in the second opening OP2_1, color conversion efficiency of light may increase. For example, power consumption of the display device may be reduced.

The first light scattering pattern LSP2_1, the first sub-light conversion pattern CCP2_1, the second light scattering pattern LSP2_2, and the second sub-light conversion pattern CCP2_2 may be sequentially disposed in the second opening OP2_2 corresponding to the second sub-pixel SP2.

Each of the first and second light scattering patterns LSP2_1 and LSP2_2, and the first and second sub-light conversion patterns CCP2_1 and CCP2_2 may be configured similarly to each of the first and second light scattering patterns LSP1_1 and LSP1_2, and the first and second sub-light conversion patterns CCP1_1 and CCP1 2.

However, thicknesses of the first and second light scattering patterns LSP1_1 and LSP1_2 disposed in the second opening OP2_1 and the first and second light scattering patterns LSP2_1 and LSP2_2 disposed in the second opening OP2_2 may be different from each other. For example, in case that the light conversion efficiency of the first and second sub-light conversion patterns CCP1_1 and CCP1_2 disposed in the second opening OP2_1 is lower than that of the first and second sub-light conversion patterns CCP2_1 and CCP2_2 disposed in the second opening OP2_2, the thicknesses of the first and second light scattering patterns LSP1_1 and LSP1_2 disposed in the second opening OP2_1 may be smaller than those of the first and second light scattering patterns LSP2_1 and LSP2_2 disposed in the second opening OP2_2.

Thicknesses of the first and second sub-light conversion patterns CCP1_1 and CCP1_2 disposed in the second opening OP2 corresponding to the first sub-pixel SP1 and the first and second sub-light conversion patterns CCP2_1 and CCP2_2 disposed in the second opening OP2 corresponding to the second sub-pixel SP2 may be different from each other.

In embodiments, a third passivation layer PSV3 may be disposed on the second bank BNK2, the reflective layer RFL, the second sub-light conversion patterns CCP1_2 and CCP2_2, and the light scattering pattern LSP, and a low refractive index layer LRL may be disposed on the third passivation layer PSV3.

The third passivation layer PSV3 may protect components disposed thereunder, and may provide a flat upper surface. The third passivation layer PSV3 may include a same material as the first passivation layer PSV1, but embodiments are not limited thereto.

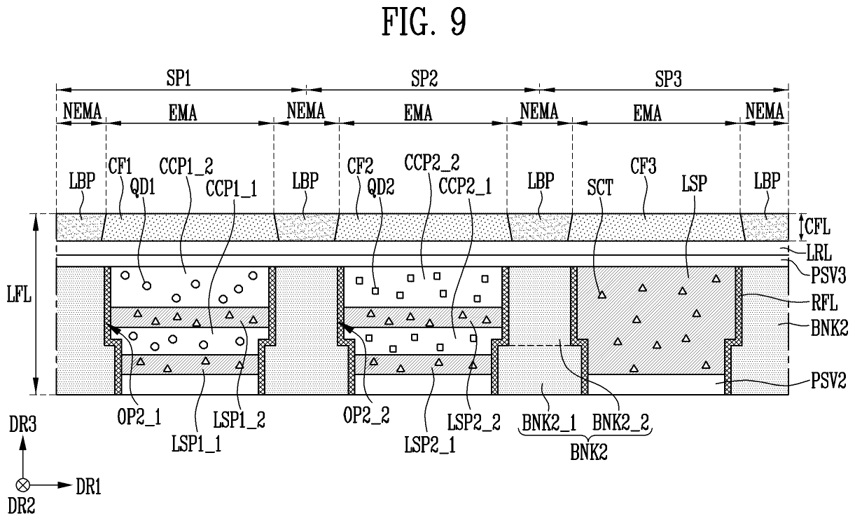

FIG. 9 illustrates a schematic cross-sectional view of a light functional layer of FIG. 7 according to an embodiment.

Referring to FIG. 7 and FIG. 9, the light functional layer LRL having a multilayer formed in second openings OP2_1 and OP2_2 corresponding to the first and second sub-pixels SP1 and SP2 is illustrated. Since the light functional layer LRL of FIG. 9 is similar to the light functional layer LRL of FIG. 8, redundant descriptions thereof may be omitted.

Referring to FIG. 9, the second bank BNK2 may include a first sub-bank BNK2_1 and a second sub-bank BNK2_2 disposed on the first sub-bank BNK2_1. The first sub-bank BNK2_1 and the second sub-bank BNK2_2 may have different widths in the first direction DR1. In embodiments, the width of the first sub-bank BNK2_1 in the first direction DR1 may be greater than that of the second sub-bank BNK2_2 in the first direction DR1.

The first sub-bank BNK2_1 and the second sub-bank BNK2_2 may be made of a same material. The thicknesses of the first sub-bank BNK2_1 and the second sub-bank BNK2_2 may be different from each other.

As the second bank BNK2 may include the first sub-bank BNK2_1 and the second sub-bank BNK2_2, the second sub-light conversion patterns CCP1_2 and CCP2_2 may have a thicker thickness than the first sub-light conversion patterns CCP1_1 and CCP2_1.

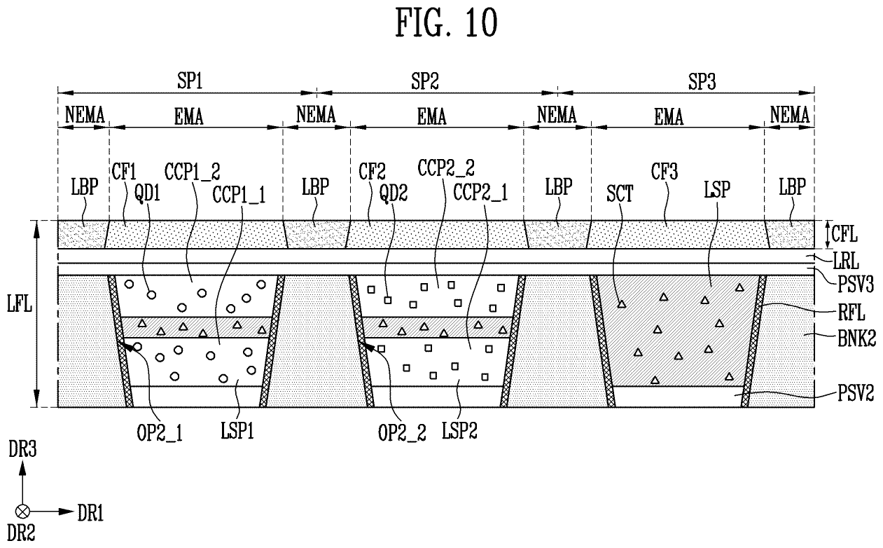

FIG. 10 illustrates a schematic cross-sectional view of a light functional layer of FIG. 7 according to an embodiment.

Referring to FIG. 7 and FIG. 10, the light functional layer LRL having a multilayer formed in second openings OP2_1 and OP2_2 corresponding to the first and second sub-pixels SP1 and SP2 is illustrated. Since the light functional layer LRL of FIG. 10 is similar to the light functional layer LRL of FIG. 8, redundant descriptions thereof may be omitted.

The first sub-light conversion pattern CCP1_1, the first light scattering pattern LSP1, and the second sub-light conversion pattern CCP1_2 may be sequentially disposed in the second opening OP2_1 corresponding to the first sub-pixel SP1.

The first light scattering pattern LSP1 may include scattering particles SCT that scatter blue-colored light in order to improve light output efficiency. The first and second sub-light conversion patterns CCP1_1 and CCP1_2 may include first color conversion particles QD1 configured to convert blue-colored light into red-colored light.

The first sub-light conversion pattern CCP1_1 may convert the first light, which is a portion of the first reference light emitted from the first light emitting element LD1, into red colored light.

The first light scattering pattern LSP1 may scatter the second light, which is the remainder of the first reference light, to provide it to the second sub-light conversion pattern CCP1_2, or may recycle the second light to provide it to the first sub-light conversion pattern CCP1_1. The second light may be light that has not been converted by the first sub-light conversion pattern CCP1_1.

By way of non-limiting example, the first light scattering pattern LSP1_1 may provide the first sub-light, which is a portion of the second light, to the first sub-light conversion pattern CCP1_1, or the second sub-light, which is the remainder of the second light, to the second sub-light conversion pattern CCP1_2.

The first sub-light conversion pattern CCP1_1 may convert the first sub-light returned from the second light scattering pattern LSP1_2 into red colored light. The second sub-light conversion pattern CCP1_2 may convert the second sub-light into red-colored light.

In embodiments, the second sub-light conversion pattern CCP1_2 may convert light that is not converted by the first sub-light conversion pattern CCP1_1 among the first sub-light into red-colored light.

The first sub-light conversion pattern CCP2_1, the second light scattering pattern LSP2, and the second sub-light conversion pattern CCP2_2 may be sequentially disposed in the second opening OP2_2 corresponding to the second sub-pixel SP2.

Each of the second light scattering pattern LSP2 and the first and second sub-light conversion patterns CCP2_1 and CCP2_2 may be configured similarly to each of the first light scattering patterns LSP1_1 and the first and second sub-light conversion patterns CCP1_1 and CCP1_2.

In embodiments, as described in FIG. 9, the second bank BNK2 may include a first sub-bank BNK2_1 and a second sub-bank BNK2_2 disposed on the first sub-bank BNK2_1.

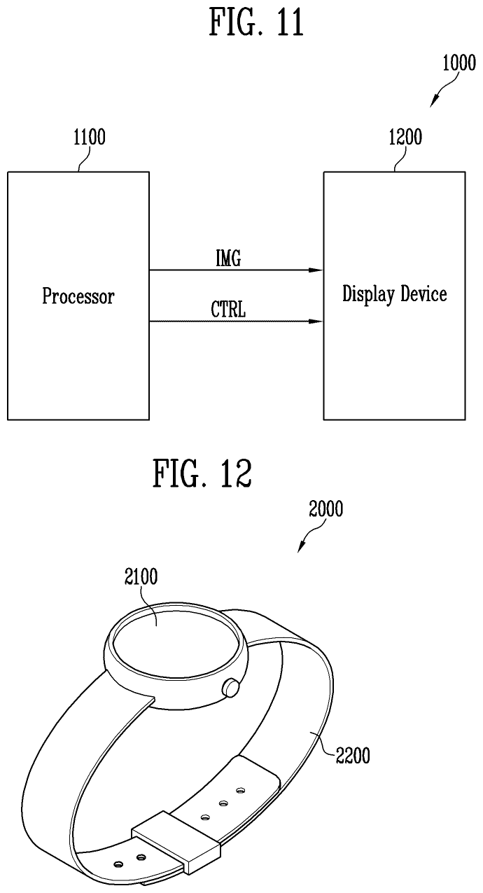

FIG. 11 illustrates a block diagram of an embodiment of a display system.

Referring to FIG. 11, a display system 1000 may include a processor 1100 and a display device 1200.

The processor 1100 may perform various tasks and calculations. In embodiments, the processor 1100 may include an application processor, a graphics processor, a microprocessor, a central processing unit (CPU), and the like within the spirit and the scope of the disclosure. The processor 1100 may be connected to and step other constituent elements of the display system 1000 through a bus system.

The processor 1100 may transmit image data IMG and a control signal CTRL to the display device 1200. The display device 1200 may display an image based on the image data IMG and the control signal CTRL. The display device 1200 may be configured similarly to the display device DD described with reference to FIG. 1. In this case, the image data IMG and the control signal CTRL may be provided as the input image data IMG and the control signal CTRL of FIG. 1, respectively.

The display system 1000 may include a computing system that provides image display functions such as a smart watch, a mobile phone, a smart phone, a portable computer, a tablet personal computer (PC), a watch phone, an automatic display, a smart glass, a portable multimedia layer (PMP), a navigation system, and an ultra mobile personal computer (UMPC). The display system 1000 may include at least one of a head-mounted display device (HMD), a virtual reality (VR) device, a mixed reality (MR) device, and an augmented reality (AR) device.

FIG. 12 to FIG. 15 illustrate schematic perspective views of application examples of the display system of FIG. 11.

Referring to FIG. 12, the display system 1000 of FIG. 11 may be applied to a smart watch 2000 including a display portion 2100 and a strap portion 2200.

The smart watch 2000 may be a wearable electronic device. For example, the smart watch 2000 may have a structure in which the strap portion 2200 is mounted on the user's wrist. Here, the display system 1000 and/or the display device 1200 may be applied to the display portion 2100, so that image data including time information may be provided to the user.

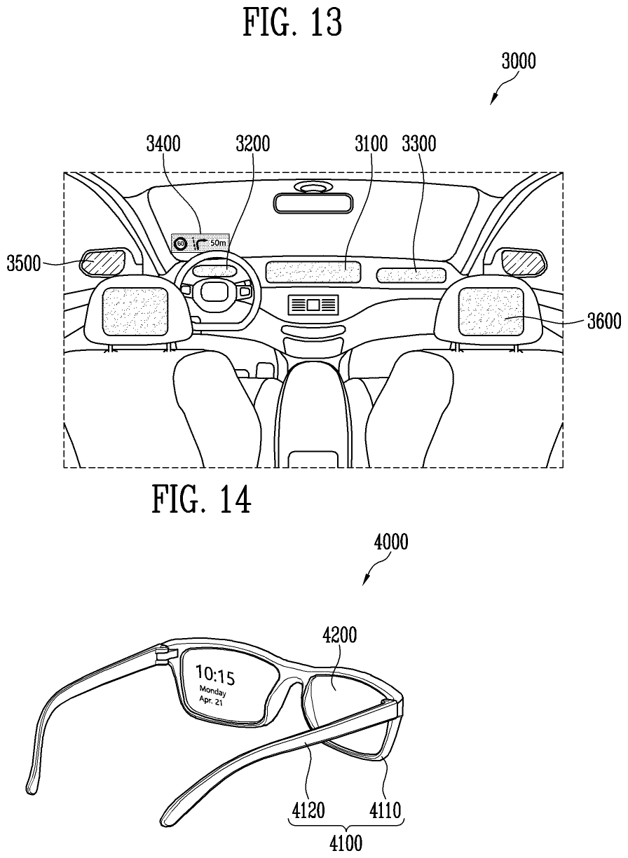

Referring to FIG. 13, the display system 1000 of FIG. 11 may be applied to an automotive display system 3000. Here, the automotive display system 3000 may include a computing system that is provided inside and/or outside the vehicle to provide image data.

For example, the display system 1000 and/or the display device 1200 may be applied to at least one of an infotainment panel 3100, a cluster 3200, a co-driver display 3300, a head-up display 3400, a side mirror display 3500, and a rear-seat display 3600, which are provided in the vehicle.

Referring to FIG. 14, the display system 1000 of FIG. 11 may be applied to smart glasses 4000. The smart glasses 4000 may be a wearable electronic device that may be worn on the user's head. For example, the smart glasses 4000 may be a wearable device for augmented reality.

The smart glasses 4000 may include a frame 4100 and a lens portion 4200. The frame 4100 may include a housing 4110 supporting the lens portion 4200 and a leg portion 4120 for the user to wear. The leg portion 4120 may be connected to the housing 4110 through a hinge to be folded or unfolded with respect to the housing 4110.

A battery, a touch pad, a microphone, and a camera may be embedded in the frame 4100. A projector that outputs light and a processor that controls a light signal and the like may be embedded in the frame 4100.

The lens portion 4200 may include an optical member that transmits light or reflects light. For example, the lens portion 4200 may include glass, a transparent synthetic resin, or the like within the spirit and the scope of the disclosure.

In order for the user's eyes to recognize visual information, the lens portion 4200 may reflect an image by a light signal transmitted from the projector of the frame 4100 by a rear surface of the lens portion 4200 (for example, a surface facing the user's eye). For example, the user may recognize visual information such as time and date displayed on the lens part 4200. In this case, the projector and/or the lens portion 4200 may be a type of display device. The display device 1200 may be applied to the projector and/or the lens portion 4200.

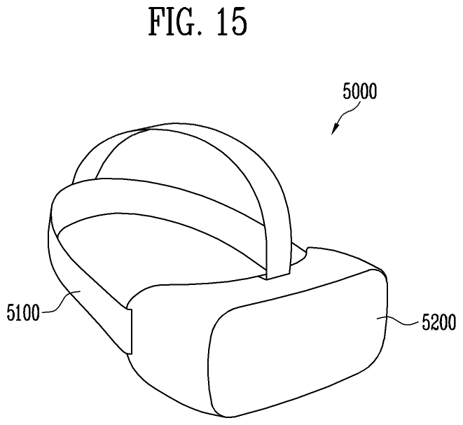

Referring to FIG. 15, the display system 1000 of FIG. 11 may be applied to a head-mounted display device 5000.

The head-mounted display device 5000 may be a wearable electronic device that may be worn on the user's head. For example, the head-mounted display device 5000 may be a wearable device for virtual reality or mixed reality.

The head-mounted display device 5000 may include a head-mounted band 5100 and a display device accommodation case 5200. The head-mounted band 5100 may be connected to the display device accommodation case 5200. The head-mounted band 5100 may include a horizontal band and/or a vertical band for fixing the head-mounted display device 5000 to the user's head. The horizontal band may be configured to surround the side portion of the user's head, and the vertical band may be configured to surround the upper portion of the user's head. However, embodiments are not limited thereto. For example, the head-mounted band 5100 may be implemented in the form of a spectacle frame, a helmet, or the like within the spirit and the scope of the disclosure.

The display device accommodation case 5200 may accommodate the display system 1000 and/or the display device 1200.

Although embodiments and implementations have been described herein, other embodiments and modifications will be apparent from this description. Accordingly, the disclosure is not limited to the embodiments, but rather to the broader scope of the presented claims and various obvious modifications and equivalent arrangements.

What is claimed is:

1. A display device comprising:
a light functional layer disposed on a substrate, wherein
the light functional layer includes:
a bank having a plurality of openings,
a first light scattering pattern, a first sub-light conversion pattern, a second light scattering pattern, and a second sub-light conversion pattern sequentially disposed in a first opening of the plurality of openings, and
a thickness of each of the first sub-light conversion pattern and the second sub-light conversion pattern is thicker than a thickness of the first light scattering pattern and the second light scattering pattern.

2. The display device of claim 1, further comprising:
a display element layer disposed between the substrate and the light functional layer, wherein
the display element layer includes a first light emitting element, a second light emitting element and a third light emitting element respectively corresponding to a first sub-pixel, a second sub-pixel and a third sub-pixel,
the first light scattering pattern scatters first reference light emitted from the first light emitting element to provide a first sub-light conversion pattern,
the first sub-light conversion pattern converts a color of first light that is a portion of the first reference light, and
the second light scattering pattern provides second light that is a remainder of the first reference light to the first sub-light conversion pattern and the second sub-light conversion pattern.

3. The display device of claim 2, wherein the second light is light of color not converted by the first sub-light conversion pattern.

4. The display device of claim 2, wherein the second light scattering pattern provides first sub-light that is a portion of the second light to the first sub-light conversion pattern and provides second sub-light that is a remainder of the second light to the second sub-light conversion pattern.

5. The display device of claim 4, wherein the second sub-light conversion pattern converts a color of the second sub-light.

6. The display device of claim 4, wherein the second sub-light conversion pattern converts a color of light of the first sub-light that is not converted by the first sub-light conversion pattern.

7. The display device of claim 2, wherein
a first light scattering pattern, a first sub-light conversion pattern, a second light scattering pattern, and a second sub-light conversion pattern are sequentially disposed in a second opening of the plurality of openings, and
the first opening corresponds to the first sub-pixel,
the second opening corresponds to the second sub-pixel, and
thicknesses of the first light scattering pattern and the second light scattering pattern disposed in the first opening are different from thicknesses of the first light scattering pattern and the second light scattering pattern disposed in the second opening.

8. The display device of claim 7, wherein thicknesses of the first sub-light conversion pattern and the second sub-light conversion pattern disposed in the first opening are different from thicknesses of the first sub-light conversion pattern and the second sub-light conversion pattern disposed in the second opening.

9. The display device of claim 2, wherein a passivation layer is disposed on the bank and the second sub-light conversion pattern.

10. The display device of claim 9, wherein a low refractive index layer is disposed on the passivation layer.

11. The display device of claim 2, wherein
the bank includes a first sub-bank and a second sub-bank disposed on the first sub-bank,
a width of the first sub-bank in a first direction is greater than a width of the second sub-bank in the first direction, and
the first direction is a direction in which the first sub-pixel, the second sub-pixel and the third sub-pixel are disposed.

12. The display device of claim 1, wherein a number of scattering particles included in the first light scattering pattern is less than a number of scattering particles included in the second light scattering pattern.

13. The display device of claim 12, wherein
a refractive index of the first light scattering pattern is about 1.5 or less, and
a refractive index of the second light scattering pattern is about 1.5 or more.

14. The display device of claim 1, wherein thicknesses of the first light scattering pattern, the first sub-light conversion pattern, the second light scattering pattern, and the second sub-light conversion pattern are different.

15. A display device comprising:
a light functional layer disposed on a substrate, wherein
the light functional layer includes a bank having a plurality of openings,
a first sub-light conversion pattern, a light scattering pattern, and a second sub-light conversion pattern are sequentially disposed in a first opening of the plurality of openings, and
a thickness of each of the first sub-light conversion pattern and the second sub-light conversion patterns is thicker than a thickness of the light scattering pattern.

16. The display device of claim 15, further comprising:
a display element layer disposed between the substrate and the light functional layer, wherein
the display element layer includes a first light emitting element, a second light emitting element and a third light emitting element respectively corresponding to first sub-pixel, a second sub-pixel and a third sub-pixel,
the first sub-light conversion pattern converts a color of first light that is a portion of first reference light emitted from the first light emitting element, and
the light scattering pattern provides second light that is a remainder of the first reference light to the first sub-light conversion pattern and the second sub-light conversion pattern.

17. The display device of claim 16, wherein the second light is light of color not converted by the first sub-light conversion pattern.

18. The display device of claim 16, wherein the light scattering pattern provides first sub-light that is a portion of the second light to the first sub-light conversion pattern and provides second sub-light that is a remainder of the second light to the second sub-light conversion pattern.

19. The display device of claim 18, wherein the second sub-light conversion pattern converts a color of light of the second sub-light and the first sub-light that is not converted by the first sub-light conversion pattern.

20. A display system comprising:
a processor that provides image data and a control signal; and
a display device including a display panel to display an image corresponding to the image data in response to the control signal, wherein
the display panel includes:
a light functional layer disposed on a substrate, and
the light functional layer includes a bank having a plurality of openings;
a first light scattering pattern, a first sub-light conversion pattern, a second light scattering pattern, and a second sub-light conversion pattern sequentially disposed in a first opening of the plurality of openings; and
a thickness of each of the first sub-light conversion pattern and second light scattering pattern and second sub-light conversion patterns is thicker than a thickness of the first and second light scattering patterns.
